(19) United States
(12) Patent Application Publication
(10) Pub. No.: US 2015/0380325 A1
(43) Pub. Date: Dec. 31, 2015

(54) PHYSICAL LAYOUT FEATURES OF INTEGRATED CIRCUIT DEVICE TO ENHANCE OPTICAL FAILURE ANALYSIS

(71) Applicant: QUALCOMM Incorporated, San Diego, CA (US)

(72) Inventors: Ulrike KINDEREIT, Del Mar, CA (US); Lavakumar RANGANATHAN, San Diego, CA (US)

(21) Appl. No.: 14/315,324

(22) Filed: Jun. 25, 2014

(51) Int. Cl. H01L 21/66; G01R 1/07; H01L 27/092

(52) U.S. Cl. CPC H01L 22/32; H01L 27/092; G01R 1/07

(57) ABSTRACT

An integrated circuit device includes an active silicon layer, and at least one passive metal layer placed in an input region and an output region of the device. The at least one passive metal layer has a surface area and thickness for at least one of the input region or the output region to provide a phase shift of an optical laser, the phase shift corresponding to an optimized visibility of the optical laser during an optic failure analysis of the device.

### BACKGROUND

1. Field

The present disclosure relates generally to integrated circuit (IC) devices, and more particularly, to physical layout features of nodes on a very large scale integration (VLSI) structure that enhances optical failure analysis.

2. Background

A Laser Voltage Probing System is a laser-based, all-optical failure analysis tool that measures electrical activity of integrated circuit (IC) devices (nodes) through the thinned backside the IC structure. The signal is generated by focusing an infra-red laser onto the electrically active areas in the tested device, and reflecting the laser off of the interfaces in the field of view. Electrical activity (i.e., voltage indicating ON/OFF state) of the device changes the optical properties of the device and hence modulates the reflected light accordingly. This modulation is the actual Laser Voltage Probing (LVP) signal showing the device activity. Static interference effects (destructive or constructive) strongly influence this original signal and hence have a major impact on the signal generation. With LVP, the laser is pointed to a specific position of interest in the device and the modulation in the reflected light is recorded over time. The extracted information is similar to a waveform on an oscilloscope, having no quantitative voltage level information, but containing timing information of the waveform.

Laser Voltage Imaging, LVI, scans a laser across an area of interest and the modulation amplitude in the frequency-domain is correlated to the x/y coordinate of the device under test. A modulation map is created giving visual information about the location of device activity.

IC devices continue to shrink in size as VLSI technology advances, making conventional LVP and LVI techniques more challenging. In fact, current device sizes have reached an order of magnitude smaller than the dimension that a commercial LVP tool can resolve. Also, static interference effects can occur as underlying and neighboring structures of the IC physical layout (e.g., interconnect, contact and metal layers, vias and shallow trench isolation (STI) borders) can enhance or cancel the original signal caused by the device activity. Recent advancements to IC devices have brought reduced voltage specifications, posing even further challenges to LVP and LVI tools, as the signal to be detected by optical reflection diminishes to levels below detectable thresholds.

### SUMMARY

An integrated circuit (IC) device comprises passive metal layers configured to provide a desired phase shift of an optical laser, the phase shift corresponding to an optimized visibility of the optical laser during an optical failure analysis (e.g., LVP or LVI) of the IC device. The metal layers provide interconnections between an active silicon layer and external pins. The shape and size of the metal layer configurations may be adjusted based on destructive interference and/or reflection of the optical laser used in the optical failure analysis in order to improve signal collection during the optical failure analysis.

### BRIEF DESCRIPTION OF THE DRAWINGS

FIG. 1 is a block diagram of an example IC device with multiple metal layers to optimize optical failure analysis.

FIG. 2 is a block diagram of an example IC device with multiple upper metal layers to optimize optical failure analysis.

FIG. 3 is a block diagram of an example IC device with multiple interconnection vias to optimize optical failure analysis.

FIG. 4A is a physical layout schematic of the active lower layers of an example IC device.

FIG. 4B is a physical layout schematic of the middle layers of an example IC device illustrating adjustable sizing of the layer material at the output region of the device.

FIG. 4C is a physical layout schematic of the upper metal layer of an example IC device illustrating adjustable sizing of the layer material at the output region of the device.

FIG. 5A is a physical layout schematic of the middle layers of an example IC device illustrating adjustable sizing of the layer material at the input region of the device.

FIG. 5B is a physical layout schematic of the upper metal layer of an example IC device illustrating adjustable sizing of the layer material at the input region of the device.

FIG. 6A is a physical layout schematic of the middle layers of an example IC device illustrating adjustable sizing of the layer material around a source voltage connection of the device.

FIG. 6B is a physical layout schematic of the upper metal layer of an example IC device illustrating adjustable sizing of the layer material around a source voltage connections of the device.

FIG. 7A is a physical layout schematic of the middle layers of an example IC device illustrating minimized sizing of the layer material at the input and output regions and at the source voltage connections of the device.

FIG. 7B is a physical layout schematic of the upper metal layer of an example IC device illustrating minimized sizing of the layer material at the input and output regions and at the source voltage connections of the device.

FIG. 8A is a physical layout schematic of the active lower layers of an example IC device having multiple fingers.

FIG. 8B is a physical layout schematic of the middle layers of an example IC device illustrating spacing between the input, output and source voltage connection.

FIG. 8C is a physical layout schematic of the upper metal layer of an example IC device illustrating spacing between the input, output and source voltage connection.

FIG. 9A is a physical layout schematic of the active lower layers of an example IC device having multiple fingers.

FIG. 9B is a physical layout schematic of the middle layers of an example IC device illustrating spacing between the input, output and source voltage connection.

FIG. 9C is a physical layout schematic of the upper metal layer of an example IC device illustrating spacing between the input, output and source voltage connection.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Several aspects of an integrated circuit (IC) will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented with a “processing system” that includes one or more processors. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise.

Accordingly, in one or more exemplary embodiments, the functions described may be implemented in hardware, software, firmware, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can comprise a random-access memory (RAM), a read-only memory (ROM), an electrically erasable programmable ROM (EEPROM), compact disk ROM (CD-ROM) or other optical disk storage, magnetic disk storage or other magnetic storage devices, or any other medium that can be used to carry or store desired program code in the form of instructions or data structures and that can be accessed by a computer. Combinations of the above should also be included within the scope of computer-readable media.

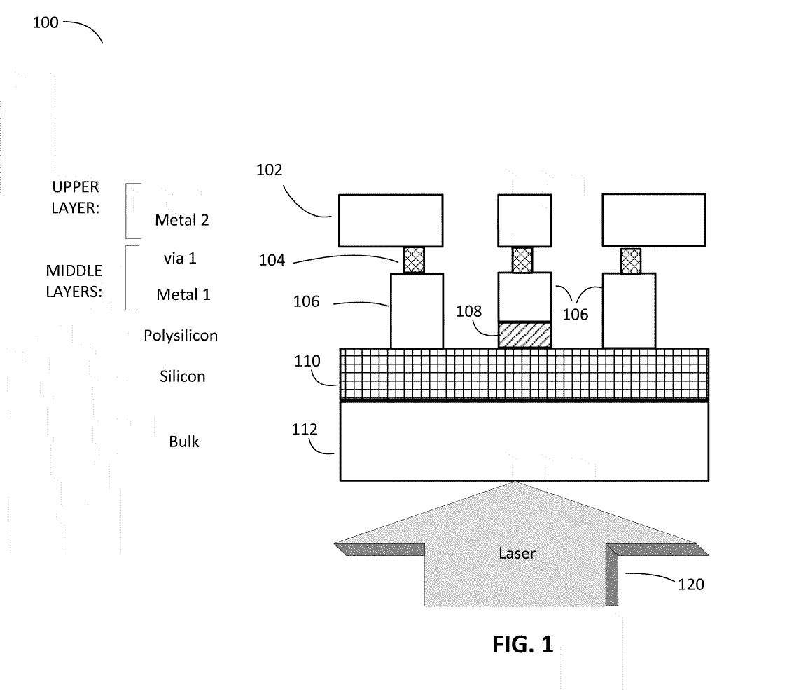

FIG. 1 is a block diagram illustrating layers of an IC device 100, as a cross-sectional view. Examples of an IC device 100 include a CMOS inverter, or any other similar functioning device. The CMOS example shown and described herein is presented as an example for demonstration purposes, and other active devices may have physical layout features configured and adjusted in a similar way according to the aspects described herein. Other examples of such devices may include, but are not limited to, diodes, capacitors, transistors, or alike active devices that carry an electric charge or switch a voltage that is detectable by an optical failure analysis tool, such as LVP or LVI.

As shown in FIG. 1, the IC device 100 is constructed of various layers. In the example of a CMOS device 100, the silicon layer 110 is used to form sources and drains of PMOS/NMOS elements, and the polysilicon layer 108 is used to form the gates. The polysilicon layer 108 also includes a silicon dioxide film at the junction with the silicon layer 110 to form the gate. These are the active layers which will operate the IC device. A bulk layer 110 creates a substrate for the device, and the optical laser 120 is applied at the outer surface of this layer. The upper metal layer 102 is positioned on the opposite surface of the device from the base bulk layer 112, and allows external connections to each of the gate, source and drain elements by way of their respective stacks. The middle layers, metal layer 106 and via 104, are passive and are configured as interconnection layers that connect the active layer elements to external connections.

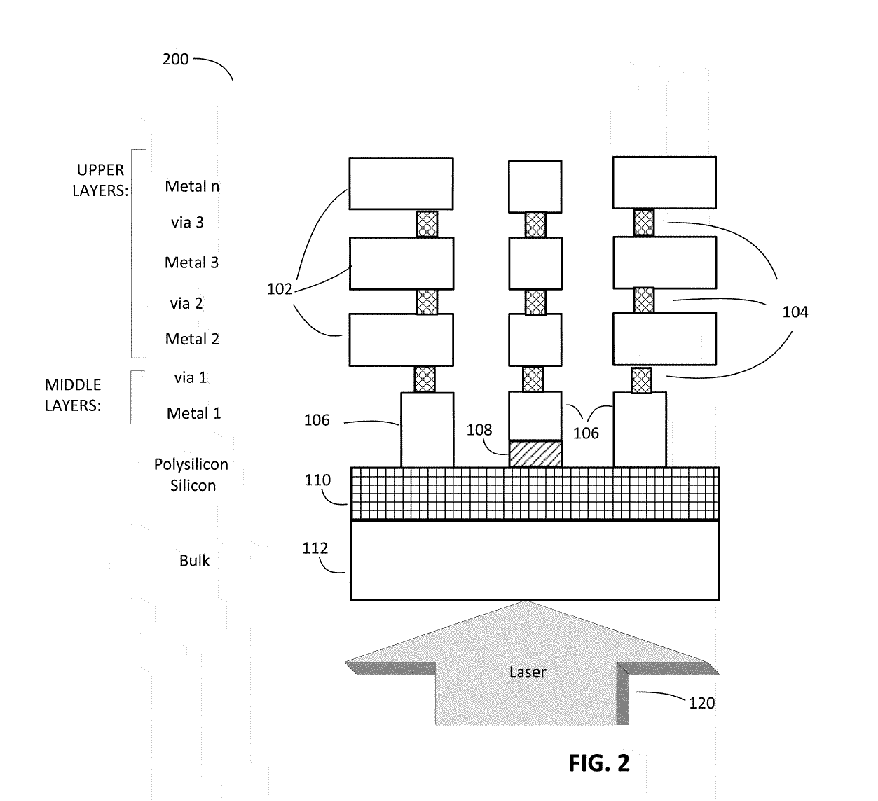

FIG. 2 is a block diagram illustrating the layers of an alternative aspect shown in FIG. 1. Here, several upper metal layers may be used, shown as layers 102, which are above via 1 in layer 104. Applying multiple metal layers 102 with vias in between may be useful for optimizing the effect on phase shift of the optical analysis device, such as LVP or LVI, as the optical laser 120 is projected through the multiple layers, entering at the bulk 112 surface.

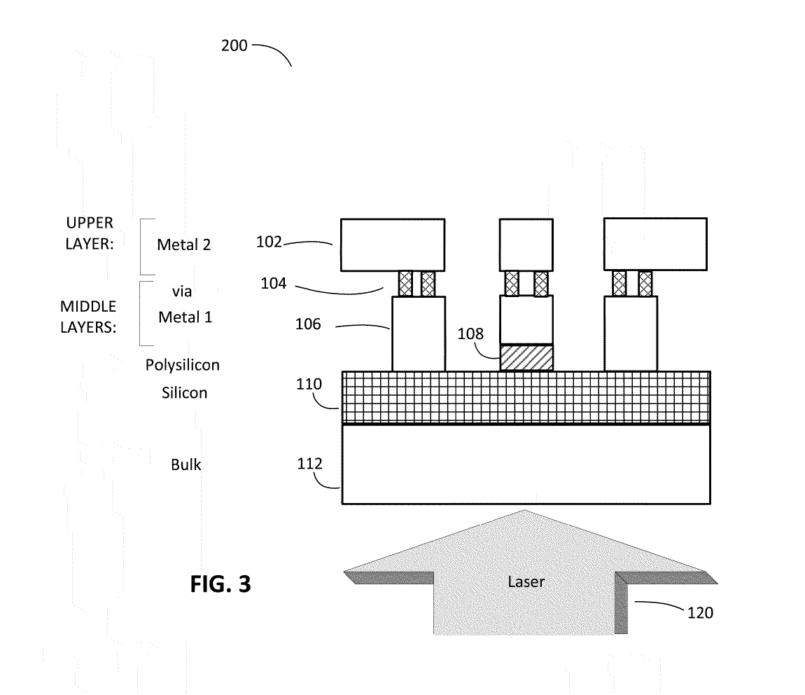

FIG. 3 is a block diagram illustrating the layers of an alternative aspect shown in FIG. 1. Here, several vias in the via layer 104 may be used as side-by-side spot connections to the layer above and below. For example, a via is typically a small single spot connection between intersecting layers. However, according to the aspect described herein where the surface area of passive metal layers 106 and 102 may be intentionally extended and expanded, this aspect as shown in FIG. 3 allows multiple via layer 104 spot connections to be laid down on the metal layer 106 below for interconnection with the upper metal layer 102. Applying multiple vias in the via layer 104 may have useful application based on the reflective property of this material as the optical laser 120 is projected through the multiple layers, entering at the bulk 112 surface.

Aspects presented herein include selecting parameters for the physical layout of semiconductor devices in order to improve signal collection by improving signal strength for optical failure analysis applications such as LVP and LVI. Signal strength for such failure analysis is enhanced by adjusting the physical layout of the semiconductor device in order to cause constructive interference. A modified cell or node of a VLSI array (e.g., a modified semiconductor device) can be configured using the adjusted parameters, and such modified cells may be used to replace standard cells in strategic circuit locations. Alternately, all cells or nodes may be engineered to enhance failure analysis signals.

In one aspect, phase shifting materials may be adjusted in the field of view of the optical analysis tool in order to improve signal collection. For example, a phase shift may be configured between a PFET and NFET due to an additional well. A phase shift may be configured at every interface with n1>n2, e.g., for a π-case, or for n1<n2, e.g., in the σ-case, and at metal layers.

Aspects may include selecting any of the shape, layout, density, and coverage of metallization and interconnect layers or vias, e.g., any of metal 102 layer, via 104 layer, passive metal 106 layer in order to improve signal collection for failure analysis.

For the case where the device is CMOS or MOSFET, aspects may include selecting drain/source diffusion dimensions and placement, for the case of a CMOS or MOSFET device, with corresponding input and output connection in order to improve signal collection for failure analysis. Aspects may also include adjusting the dimension of the gates, including, e.g., widths and numbers of fingers in order to improve signal collection for failure analysis. Aspects may include selecting the placement and/or shape of shallow trench isolation (STI) in order to improve signal collection for failure analysis.

Aspects may include the placement of dummy fill or at least one dummy layer in order to improve signal collection for optical failure analysis.

Aspects may include providing additional (deep) pn-junctions in order to improve signal collection for failure analysis.

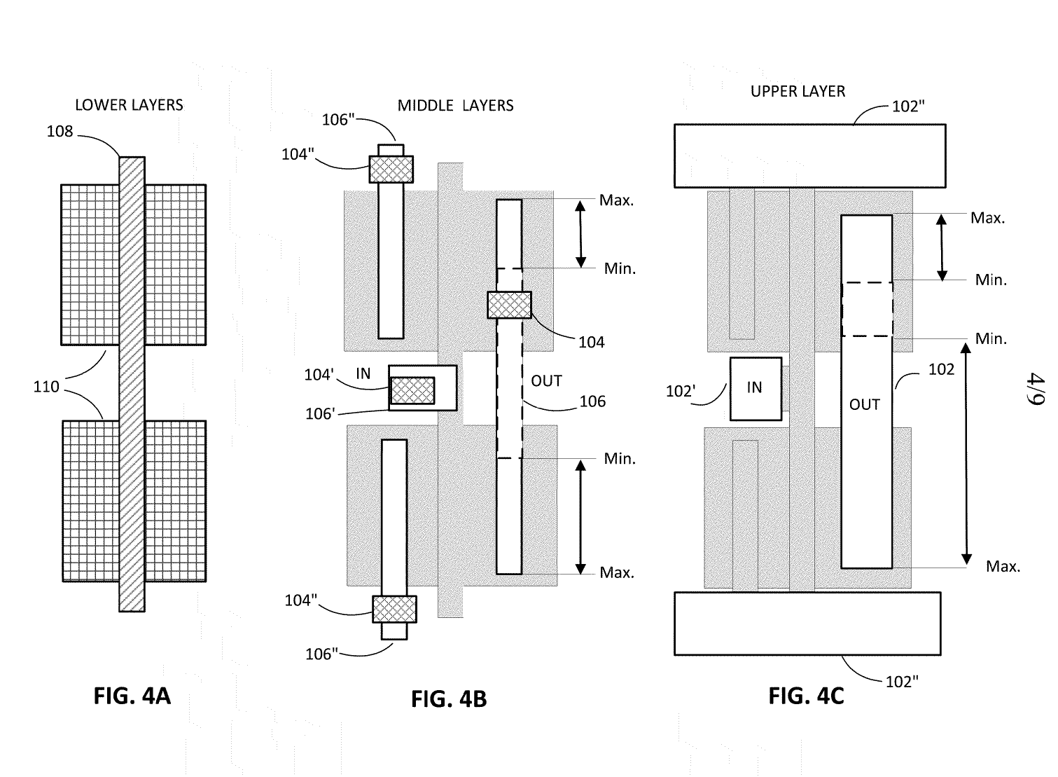

FIG. 4A is a physical layout schematic of the active lower layers of an IC device. In this layer, the diffusion layer 110 is laid down to create the active material for the device 100 (e.g., a drain region and a source region for a CMOS device), and the polysilicon layer 108 may be configured as a gate for the CMOS device 100.

FIG. 4B is a physical layout schematic of the middle interconnection layers of an IC device illustrating adjustable sizing of the layer material at the output region of the device. The metal layer 106 is formed at the output region for the device 100 (e.g., the drain of a CMOS device). In this aspect, the size of the layer 106 is set between a minimum and a maximum dimension to optimize the detection of the optical tool based on the effect of the phase shift on the laser due to the amount and position of the passive metal material. The minimum dimension is defined according to a minimum amount of surface area required for the passive metal layer to form a functional interconnection between the layer above and below it, such as for example, between the silicon diffusion layer 110 and via layer 104. The maximum dimension is defined according to an amount of passive metal surface area that provides an adequate clearance to a neighboring functional region to avoid short circuiting or current leakage. For example, a maximum dimension for the metal layer 106 at the output region must include a minimum clearance to the metal layer 106′ at the input region. The remaining metal layer 106′ and 106″ regions are laid down on the diffusion layer 110 and the polysilicon layer 108 at strategic locations according to the required functionality of the electrical device 100. For example, the layer 106′ may be placed on the polysilicon layer 108 to form an interconnection layer at the gate of the CMOS device, and the layer 106″ may be placed on the diffusion layer 110 to form the source regions on the CMOS device). The via layer 104 is laid on the passive metal layer 106 for interconnection to the final metal layer 102 as shown in FIG. 4C. The via layer 104′ is placed on the layer 106′ as an interconnection to a metal layer 102′ shown in FIG. 4C. The via layer 104″ is set upon the passive metal layer 106″ as an interconnection to metal layer 102″ as shown in FIG. 4C. The layers 110 and 108, e.g. from FIG. 4A, are shown as shaded regions below the upper layers 106 and 104.

FIG. 4C is a physical layout schematic of the upper metal layer of an IC device illustrating adjustable sizing of the layer material at the output region of the device. In this aspect, the size of the metal layer 102 may be set between a minimum and a maximum dimension to optimize the detection of the optical tool based on the effect of the phase shift on the laser due to the amount and position of the metal material. The minimum dimension is defined according to a minimum amount of surface area required for the metal layer 102 to form a functional connection to the layer below it, such as for example, to the via layer 104. The maximum dimension is defined according to an amount of metal surface area that provides an adequate clearance to a neighboring functional region to avoid short circuiting or current leakage. For example, a maximum dimension for the layer 102 at the output region must include a minimum clearance to the metal layer 102′ at the input region. The remaining metal layer 102′ and 102″ regions are laid down on the via layer at strategic locations according to the required functionality of the electrical device 100. For example, the layer 102′ may be placed on the via layer 104′ to form a final layer for external connection at the gate of the CMOS device, and the layer 102″ may be placed on the via layer 110″ to form the final layer for external connection to the source regions on the CMOS device. Aspects shown in FIG. 4C may be applied alone or in combination with the aspects shown in FIG. 4B. For simplicity, layers 110 and 108, e.g. from FIG. 4A, and layers 104 and 106 from FIG. 4B are shown as shaded regions below layer 102, 102′, 102″.

For example, aspects may include increasing metal coverage of an output in order to optimize the dimensions for laser based failure analysis, e.g., LVP or LVI. A metal layer, e.g., the metal layer 102, may be maximized as shown in FIG. 4C. Alternatively, multiple metal layers 102 with via layers 104 in between each metal layer 102 (shown in FIG. 2 as Metal 2, Metal 3, Metal n and via 1, via 2 and via 3), may be maximized to cover the output with as much metal as possible. Alternatively, both the metal layer 102 and the via layer 104 may be maximized at the output.

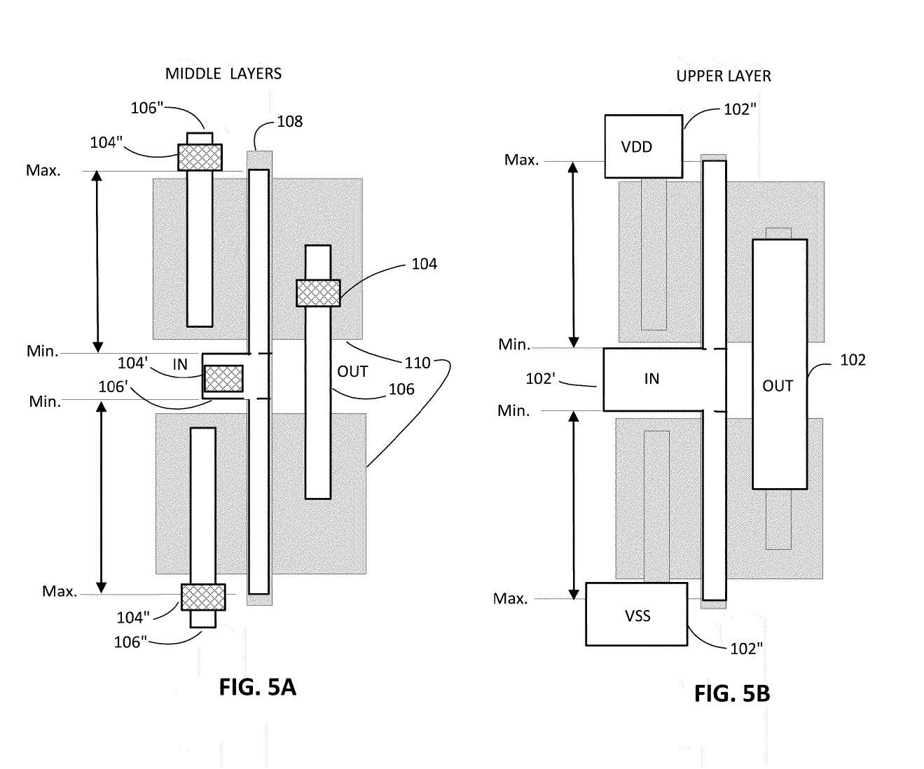

FIG. 5A is a physical layout schematic of the passive interconnection upper layers of an IC device illustrating adjustable sizing of the layer material at the input region of the device. In this aspect, as shown in FIG. 5A, the size of the layer 106′ may be set between a minimum and a maximum dimension to optimize the detection of the optical tool based on the effect of the phase shift on the laser due to the amount and position of the passive metal material. The minimum dimension is defined according to a minimum amount of surface area required for the passive metal layer to form a functional interconnection between the layer above and below it, such as for example, between the silicon diffusion layer 110′ and via layer 104′. The maximum dimension is defined according to an amount of metal surface area that provides an adequate clearance to a neighboring functional region to avoid short circuiting or current leakage. For example, a maximum dimension for the metal layer 106′ at the input region must include a minimum clearance to the metal layer 106 at the output region. The remaining metal layer 106 and 106″ regions are laid down on the diffusion layer 110 at strategic locations according to the required functionality of the electrical device 100, without regard for the optical failure analysis. In this aspect, the via layer 104, 104′ and 104″ is placed and sized according to the required interconnection functionality, without regard for the optical failure analysis. The diffusion layer 110 and polysilicon layer 108 are shown as shaded regions below the upper layers 106 and 104.

FIG. 5B is a physical layout schematic of the final metal layer of an IC device illustrating adjustable sizing of the layer material at the input region of the device. In this aspect, the size of the metal layer 102′ may be set between a minimum and a maximum dimension to optimize the detection of the optical tool based on the effect of the phase shift on the laser due to the amount and position of the metal material. The minimum dimension is defined according to a minimum amount of surface area required for the metal layer 102′ to form a functional connection to the layer below it, such as for example, to the via layer 104′. The maximum dimension is defined according to an amount of metal surface area that provides an adequate clearance to a neighboring functional region to avoid short circuiting or current leakage. For example, a maximum dimension for the layer 102′ at the input region must include a minimum clearance to the metal layer 102 at the output region. The remaining metal layer 102 and 102″ regions are laid down on the via layer 110, 110″ at strategic locations according to the required functionality of the electrical device 100. The diffusion layer 110, polysilicon layer 108, and the upper layer 106 are shown as shaded regions below the metal layer 102, 102′, 102″.

For example, aspects may include increasing metal coverage at metal layer 102′ of an input in order to optimize the reception of a reflected laser for optical failure analysis, e.g., LVP or LVI. One or more metal layers 102′ may also be maximized directly on top of a gate, e.g., without via layer 104′. This may involve a modification to metal layer 102″ for VSS and VDD connections.

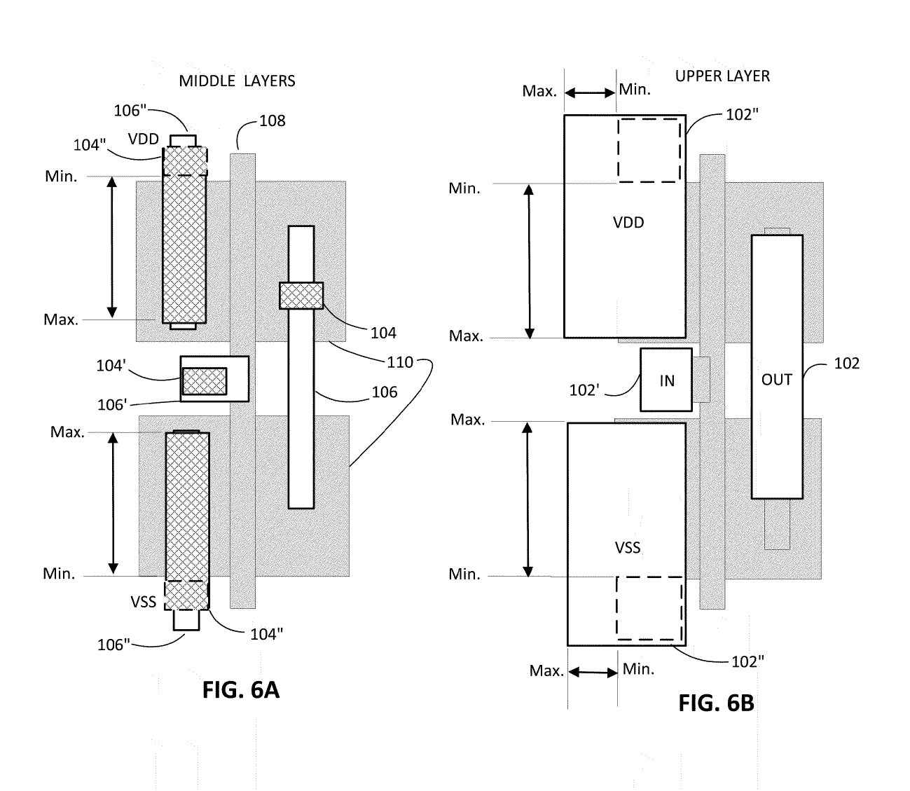

FIG. 6A is a physical layout schematic of the middle interconnection layers of an IC device illustrating adjustable sizing of the layer material around a source voltage connection of the device. The passive via interconnection layer 104″ is formed at the control voltage region for the device 100 (e.g., the source of a CMOS device). In this aspect, the size of the layer 104″ is set between a minimum and a maximum dimension to optimize the detection of the optical tool based on the effect of the phase shift on the laser due to the amount and position of the passive metal material. The minimum dimension is defined according to a minimum amount of surface area required for the passive via layer 104″ to form a functional interconnection between the layer above and below it, such as for example, between the passive metal layer 106″ and metal layer 106″. The maximum dimension is defined according to an amount of passive metal surface area that provides an adequate clearance to a neighboring functional region to avoid short circuiting or current leakage. For example, a maximum dimension for the via layer 104″ at the control voltage region must include a minimum clearance to the via layer 104 at the output region and the passive via layer 104′ at the input region. The remaining via layer 104 and 104′ regions are laid down on the metal layer 106, 106′ at strategic locations according to the required functionality of the electrical device 100. For example, the layer 104′ may be placed on the metal layer 106 to form an interconnection layer at the gate of the CMOS device, and the layer 104 may be placed on the passive metal layer 106 to form the drain regions on the CMOS device). The size and placement of the passive metal layer 106, 106′, 106″ may be set according to the required functionality of the electrical device 100. Sizing the metal layer 106″ may be based on the size of the via layer 104″ such that physical support under an enlarged via layer is provided. The layers 110 and 108 are shown as shaded regions below the upper layers 106 and 104.

FIG. 6B is a physical layout schematic of the middle metal layer of an IC device illustrating adjustable sizing of the layer material around the source voltage connections of the device. In this aspect, the size of the metal layer 102″ may be set between a minimum and a maximum dimension to optimize the detection of the optical tool based on the effect of the phase shift on the laser due to the amount and position of the metal material. The minimum dimension is defined according to a minimum amount of surface area required for the metal layer 102″ to form a functional connection to the layer below it, such as for example, to the via layer 104″. The maximum dimension is defined according to an amount of metal surface area that provides an adequate clearance to a neighboring functional region to avoid short circuiting or current leakage. For example, a maximum dimension for the layer 102″ at the control voltage region must include a minimum clearance to the metal layer 102 at the output region and to the metal layer 102′ at the input region. The remaining metal layer 102 and 102′ regions are laid down on the via layer 104, 104′ at strategic locations according to the required functionality of the electrical device 100. The diffusion layer 110, polysilicon layer 108, and the metal layer 106 are shown as shaded regions below the metal layer 102, 102′, 102″.

In an example of optimizing the dimensions for laser based failure analysis, e.g., LVP or LVI, metal coverage may be increased for source contacts, e.g., at the VSS and VDD regions. Thus, a metal layer, e.g., layer 102″ may be maximized on top of the source contacts. Additionally, a via layer, e.g., 104″, may be maximized at the source regions VDD, VSS. This may also be done in combination with the maximization of middle metal layer, e.g., layer 106″.

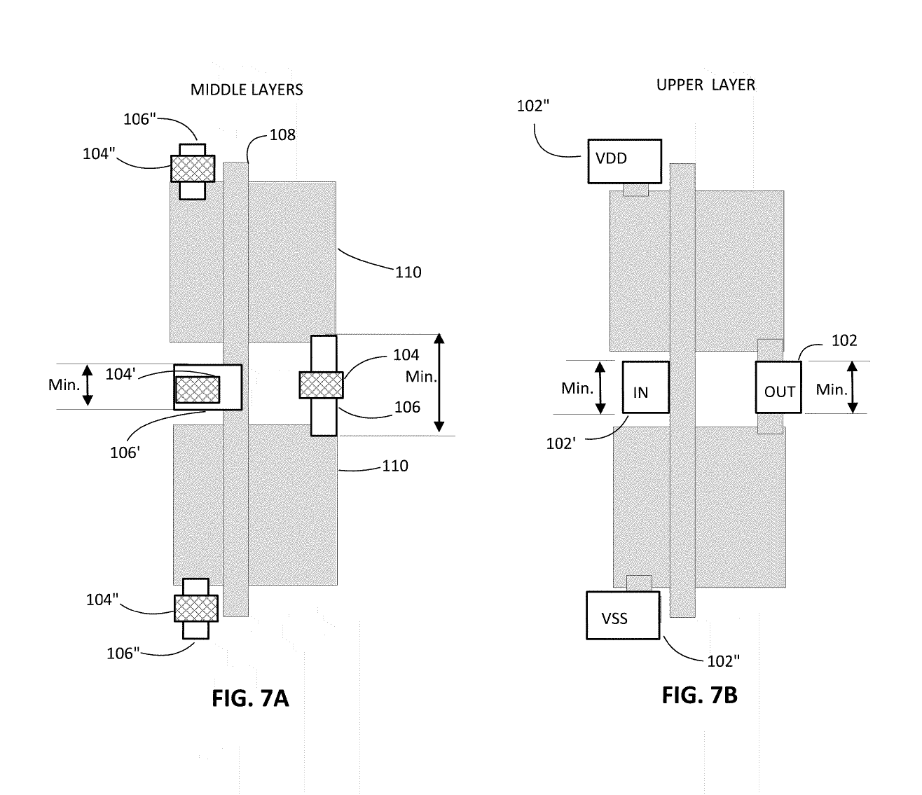

FIG. 7A is a physical layout schematic of the passive interconnection middle layers of an IC device illustrating minimized sizing of the layer material at the input and output regions and at the source voltage connections of the device. In this aspect, as shown in FIG. 7A, the size of the layer 106, 106′, 106″ may be set to a minimum dimension to minimize destructive interference of the optical laser during failure analysis. The sizing may optimize the detection of the laser based on the effect of the phase shift on the laser due to the amount and position of the metal material. The minimum dimension is defined according to a minimum amount of surface area required for the metal layer 106, 106′, 106″ to form a functional interconnection between the layer above and below it. The via layer 104, 104′, 104″ may also be sized according to a minimum dimension as shown in FIG. 7A to minimize destructive interference of the optical laser. The minimum dimension is defined according to a minimum amount of surface area required for the passive via layer 104, 104′, 104″ to form a functional interconnection between the layer above and below it. The diffusion layer 110 and polysilicon layer 108 are shown as shaded regions below the upper layers 106 and 104.

FIG. 7B is a physical layout schematic of the upper metal layer of an IC device illustrating minimized sizing of the upper metal layer material at the input and output regions and at the source voltage connections of the device. In this aspect, as shown in FIG. 7B, the size of the layer 102, 102′, 102″ may be set to a minimum dimension to minimize destructive interference of the optical laser during failure analysis. The sizing may optimize the detection of the laser based on the effect of the phase shift on the laser due to the amount and position of the passive metal material. The minimum dimension is defined according to a minimum amount of surface area required for the metal layer 102, 102′, 102″ to form a functional connection to the layer below it. Also, the placement of the metal layer 102, 102′, 102″ at the input, output and source contacts may be positioned such that spacing between these regions is maximized to reduce destructive interference.

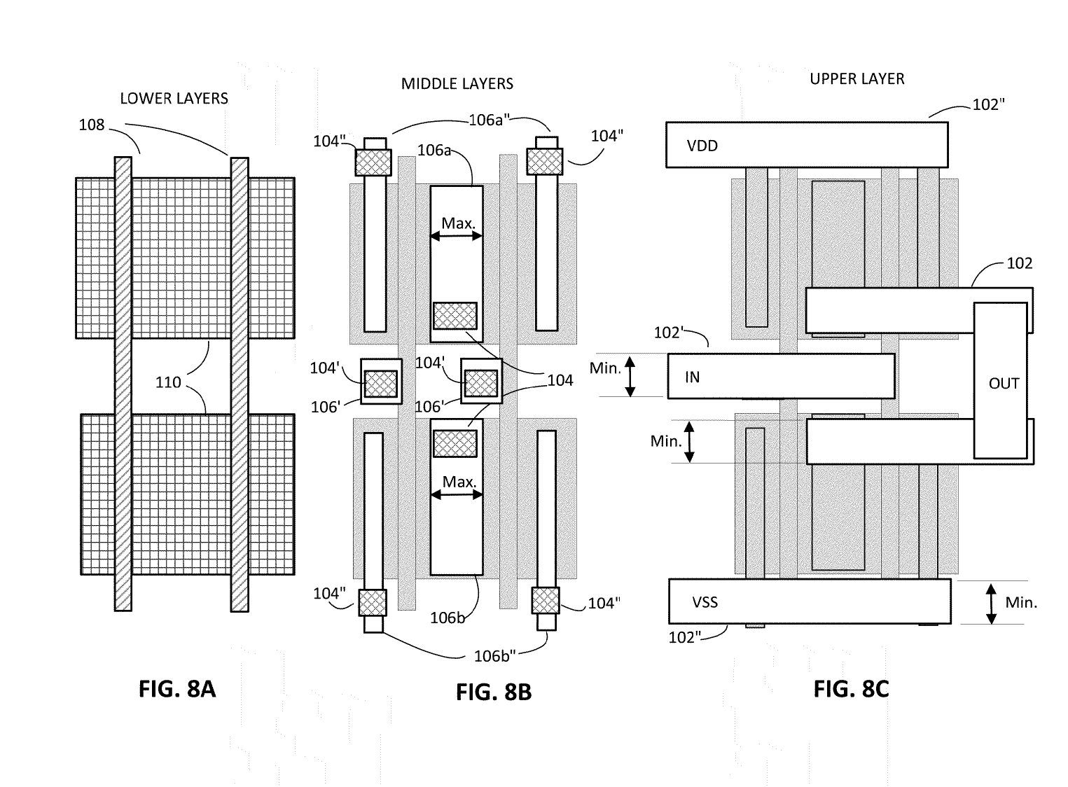

FIG. 8A is a physical layout schematic of the active lower layers of an IC device having multiple fingers. Polysilicon layer 108 may be placed on diffusion layer 110 to form a functional active layer having two fingers as shown in FIG. 8A. A layout having more than two fingers 108 may be used, but two are shown here for simplicity.

FIG. 8B is a physical layout schematic of the middle layers of a pair of IC devices illustrating spacing between the input, output and source voltage connection. Metal layers 106a and 106b may be sized to a maximum dimension so that the detection of the optical laser during the failure analysis is optimized. The maximum dimension is defined according to an amount of metal surface area that provides an adequate clearance to a neighboring functional region to avoid short circuiting or current leakage. For example, in one aspect, the metal layers 106a and 106b may each form an interconnection for drain regions for the multi-finger CMOS device 100, in which case the layer 106″ is used as interconnection for source regions of the pair of CMOS devices 100. The metal layer 106′ and 106″ regions are laid down on the diffusion layer 110 and the polysilicon layer 108 at strategic locations and sized according to the required functionality of the electrical device 100. The via layer 104 is laid on the metal layer 106 for interconnection to the metal layer 102 as shown in FIG. 8C. The via layer 104′ is placed on the layer 106′ as an interconnection to a metal layer 102′ shown in FIG. 8C. The via layer 104″ is set upon the passive metal layer 106″ as an interconnection to metal layer 102″ as shown in FIG. 8C. The layers 110 and 108 are shown as shaded regions below the upper layers 106 and 104.

FIG. 8C is a physical layout schematic of the upper metal layer of an IC device illustrating spacing between the input, output and source voltage connection. The upper metal layer 102 may be configured as shown in FIG. 8C as external connection regions for the output of the two finger device. The metal layer 102′ is placed on the via layer 102′ at the external connection region for the two finger device. The dimensions and placement of the metal layer 102, 102′ regions are set such that sufficient spacing is provided between them to prevent short circuit or leakage current. The metal layer 102″ is placed on the via layer 104″ as external connections for the source or drain, depending on the arrangement of the source and drain region interconnection layer 106″ as described above for FIG. 8B. The dimensions of the metal layer 102, 102′ 102″ regions are minimized as shown in FIG. 8C such that destructive interference to the optical laser is minimized during the failure analysis.

In one example of an inverter having multiple fingers, as described above for FIGS. 8A-8C, drain diffusions may be disposed at the center of the inverter and source diffusions may be disposed at the outer edges of the inverter. The drain diffusions may be configured to be as wide as possible, for example. In this example, additional options for improving optical failure detection using a laser include covering the drain diffusion as little as possible with passive metal layers, as much as possible with a passive metal layers (e.g., passive metal layer 106 and/or metal layer 102), or as much as possible with passive metal layers combined with a via interconnection layer, e.g., via layer 104.

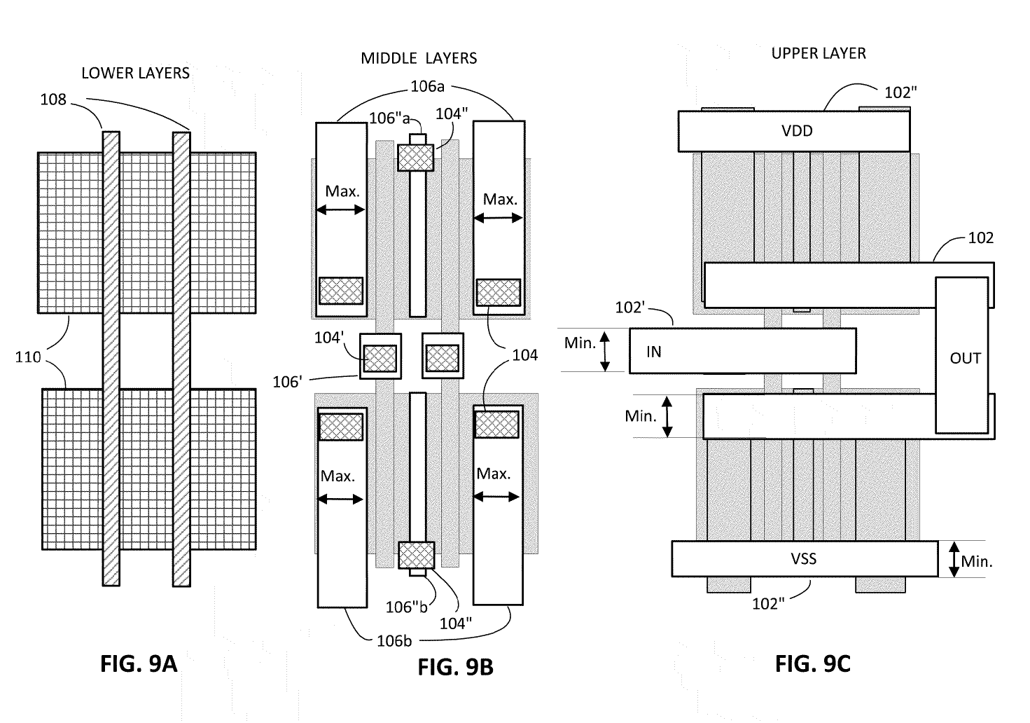

FIG. 9A is a physical layout schematic of the active lower layers of an IC device having multiple fingers. Polysilicon layer 108 may be placed on diffusion layer 110 to form a functional active layer for a CMOS device having two fingers as shown in FIG. 9A. A layout having more than two fingers 108 may be used, but two are shown here for simplicity.

FIG. 9B is a physical layout schematic of the passive interconnection middle layers of a multiple finger of IC device illustrating spacing between the input, output and source voltage connection. In contrast with FIG. 8B, the source region is placed in the center and the drain regions are placed on the outside of the device. Passive metal layers 106a and 106b may be sized to a maximum dimension so that the detection of the optical laser during the failure analysis is optimized. The maximum dimension is defined according to an amount of passive metal surface area that provides an adequate clearance to a neighboring functional region to avoid short circuiting or current leakage. For example, in one aspect, the passive metal layers 106a and 106b may each form an interconnection for drain regions for the two finger device, in which case the layer 106″ is used as interconnection for source regions of the two finger IC device. The passive metal layer 106′ and 106″ regions are laid down on the diffusion layer 110 and the polysilicon layer 108 at strategic locations and sized according to the required functionality of the electrical device 100. The via layer 104 is laid on the metal layer 106 for interconnection to the metal layer 102 as shown in FIG. 9C. The via layer 104′ is placed on the layer 106′ as an interconnection to a metal layer 102′ shown in FIG. 9C. The via layer 104″ is set upon the passive metal layer 106″ as an interconnection to metal layer 102″ as shown in FIG. 9C. The layers 110 and 108 are shown as shaded regions below the upper layers 106 and 104.

FIG. 9C is a physical layout schematic of the upper metal layer of an IC device illustrating spacing between the input, output and source voltage connection. The metal layer 102 may be configured as shown in FIG. 9C as external connection regions for the output of the two finger device. The metal layer 102′ is placed on the via layer 102′ at the external connection region for the two finger device. The dimensions and placement of the metal layers 102 and 102′ are set such that sufficient spacing is provided between them to prevent short circuit or leakage current. The metal layer 102″ is placed on the via layer 104″ as external connections for the source. The dimensions of the metal layer 102, 102′ and 102″ regions are minimized as shown in FIG. 9C such that destructive interference to the optical laser is minimized during the failure analysis.

In an example of an inverter having multiple fingers, as described above for FIGS. 9A-9C, source diffusions may be disposed at the center of the inverter and drain diffusions may be disposed at the outer edges. The drain diffusions may be extended at the outer edges. In this example, additional options for improving optical failure detection using a laser include covering the drain diffusion as little as possible with passive metal layers, as much as possible with passive metal layers, e.g., layer 106a, 106b and/or layer 102, or as much as possible with a combination of a metal layer, e.g., layer 102, and a via interconnection layer, e.g., layer 104.

In yet another example of an inverter having multiple fingers, locations of the drain diffusions and the source diffusions may be alternated, e.g., for NFET and PFET. The drain diffusion may be extended as much as possible. In this example, additional options for improving optical failure detection using a laser include covering the drain diffusion as little as possible with metal, as much as possible with a metal layer, e.g., layer 102, or as much as possible with a combination of a metal layer, e.g., layer 102 and a via interconnection layer, e.g., via layer 104.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects.” Unless specifically stated otherwise, the term “some” refers to one or more. Combinations such as “at least one of A, B, or C,” “at least one of A, B, and C,” and “A, B, C, or any combination thereof” include any combination of A, B, and/or C, and may include multiples of A, multiples of B, or multiples of C. Specifically, combinations such as “at least one of A, B, or C,” “at least one of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

1. An integrated circuit device, comprising:
an active silicon layer; and
at least one passive metal layer placed in an input region and an output region of the device,
wherein in at least one of the input region or the output region, the at least one passive metal layer is configured having a surface area and a thickness that provide a phase shift of a laser to improve visibility of the laser during an optic failure analysis of the device.

2. The device of claim 1, wherein the at least one passive metal layer is further configured having the surface area with a dimension between a minimum and a maximum dimension, wherein the maximum dimension is based on the at least one passive metal layer having a minimum clearance to a neighboring region that avoids short circuit or current leakage, and the minimum dimension is based on the at least one passive metal layer having a functional interconnection to a layer below and a layer above the at least one passive metal layer.

3. The device of claim 1, wherein the at least one passive metal layer is further configured having the surface area with a dimension that causes constructive interference in a laser generated during the optic failure analysis of the device.

4. The device of claim 3, wherein the optic failure analysis comprises using a laser voltage probing system comprising at least one of Laser Voltage Probing (LVP) or Laser Voltage imaging (LVI).

5. The device of claim 1, wherein the device comprises a CMOS device.

6. The device of claim 5, wherein the output region is configured as a drain for the CMOS device.

7. The device of claim 5, further comprising an active polysilicon layer configured as a gate region for the CMOS device at the input region.

8. The device of claim 5, wherein the at least one passive metal layer comprises at least one passive metal layer placed at a control voltage region.

9. The device of claim 8, wherein the control voltage region is configured as a source region for the CMOS device.

10. The device of claim 1, wherein the device comprises a pair of CMOS devices that share a common output region.

11. A process of fabricating an integrated circuit device comprising a plurality of layers including an active silicon layer and at least one passive metal layer, the device fabricated by a process comprising:
fabricating the at least one passive metal layer of the device located in at least one of an input, an output or a control voltage region of the device to have a dimension that provides a phase shift of a laser to improve visibility of the laser during an optical failure analysis of the device.

12. The process of claim 11, wherein the process further comprises including a number of passive metal layers located in at least one of an input, an output or a control voltage region of the device, the number of layers having a total thickness that provides a phase shift of a laser to improve visibility of the laser during an optical failure analysis of the device.

13. The process of claim 11, wherein the fabricating the at least one passive metal layer comprises setting the dimension less than or equal to a maximum dimension that provides a minimum clearance to a neighboring region and that avoids short circuit or current leakage, and greater than or equal to a minimum dimension that provides a functional interconnection to a layer below and a layer above the passive metal layer.

14. (canceled)

15. The process of claim 11, wherein the optic failure analysis comprises uses a laser voltage probing system comprising at least one of Laser Voltage Probing (LVP) or Laser Voltage Imaging (LVI).

16. The process of claim 11, wherein the device comprises a CMOS device.

17. The process of claim 16, wherein the output region is configured as a drain for the CMOS device.

18. The process of claim 16, further comprising an active polysilicon layer configured as a gate region for the CMOS device at the input region.

19. The process of claim 16, wherein the control voltage region is configured as the source region for the CMOS device.

20. The process of claim 11, wherein the device comprises a pair of CMOS devices that share a common output region.
